(19) United States
(12) Patent Application Publication
(10) Pub. No.: US 2022/0300252 A1
(43) Pub. Date: Sep. 22, 2022

(54) SUM-OF-PRODUCTS CALCULATION APPARATUS

(71) Applicant: Egis Technology Inc., Hsinchu City (TW)

(72) Inventors: Chun Hsien Su, Hsinchu City (TW); Fu-Wen Chang, Hsinchu City (TW)

(73) Assignee: Egis Technology Inc., Hsinchu City (TW)

(21) Appl. No.: 17/482,471

(22) Filed: Sep. 23, 2021

Related U.S. Application Data
(60) Provisional application No. 63/162,502, filed on Mar. 17, 2021.

(30) Foreign Application Priority Data
Aug. 23, 2021 (CN) 202110970487.6

(51) Int. Cl. G06F 7/544; G06F 7/523; G06F 7/50; H03M 1/38; H02M 7/537

(52) U.S. Cl. CPC G06F 7/5443; G06F 7/523; G06F 7/50; H03M 1/38; H02M 7/537

(57) ABSTRACT

A sum-of-products calculation apparatus is provided. The sum-of-products calculation apparatus includes an analog-to-digital conversion circuit having an encoder circuit and multiple inverters. The inverters have different threshold voltages, and generate bit signals in response to an analog sum-of-products signal. The encoder circuit encodes the bit signals to generate a digital signal.

### CROSS-REFERENCE TO RELATED APPLICATION

This application claims the priority benefit of U.S. application Ser. No. 63/162,502, filed on Mar. 17, 2021, and China application serial no. 202110970487.6, filed on Aug. 23, 2021. The entirety of each of the above-mentioned patent applications is hereby incorporated by reference herein and made a part of this specification.

### BACKGROUND

### Technical Field

The disclosure relates to a calculation apparatus, particularly to a sum-of-products calculation apparatus.

### Description of Related Art

With the development of semiconductor technology, various types of semiconductor devices are constantly being introduced. There is a novel semiconductor device that is capable of performing calculation like sum-of-product calculation, and this sum-of-products calculation is of great use for the technology of artificial intelligence.

In the conventional sum-of-products calculation apparatus, the result of the sum-of-products calculation is converted from an analog signal to a digital signal for output. Generally speaking, successive-approximation ADCs or flash-type ADCs are often used to achieve analog-to-digital signal conversion. However, the successive-approximation ADC has the disadvantages of poor working efficiency and high power consumption, whereas the flash-type ADC has the disadvantage of a large circuit area. Both of them cannot meet the requirements of the ADC for a sum-of-products calculation apparatus.

### SUMMARY

The disclosure provides a sum-of-products calculation apparatus, which has the advantages of high working efficiency, low power consumption, and small circuit area.

The sum-of-products calculation apparatus of the present disclosure includes a sum-of-products calculation circuit and an analog-digital conversion circuit. The sum-of-products calculation circuit performs a sum-of-products calculation on multiple weight signals and multiple analog input signals to output an analog sum-of-products signal. The analog-digital conversion circuit is coupled to the sum-of-products calculation circuit, and converts the analog sum-of-products signal into a digital signal. The analog-digital conversion circuit includes multiple inverters and an encoder circuit. The inverters are coupled to the sum-of-products calculation circuit. The inverters have different threshold voltages, and the inverters respond to the analog sum-of-products signal to generate multiple bit signals. The encoder circuit is coupled to the inverters, and encodes the bit signals to generate a digital signal.

Based on the above, the sum-of-products calculation apparatus of the embodiments of the present disclosure includes an analog-to-digital conversion circuit that has an encoder circuit and multiple inverters. The inverters have different threshold voltages respectively, and are able to generate multiple bit signals in response to analog sum-of-products signals. The encoder circuit encodes multiple bit signals to generate digital signals. In this way, the analog-to-digital conversion circuit has the advantages of high conversion efficiency, low power consumption, and small circuit area, meeting the requirements of the analog-digital conversion circuit for the sum-of-products calculation apparatus, which expands the feasibility of the sum-of-products calculation apparatus in artificial intelligence technology.

### BRIEF DESCRIPTION OF THE DRAWINGS

FIG. 1 is a circuit block diagram of a sum-of-products calculation apparatus according to an embodiment of the present disclosure.

FIG. 2 is a schematic circuit diagram of an inverter according to an embodiment of the disclosure.

FIG. 3 is a circuit block diagram of a sum-of-products calculation apparatus according to another embodiment of the present disclosure.

FIG. 4 is a circuit block diagram of a sum-of-products calculation apparatus according to yet another embodiment of the present disclosure.

FIG. 5 is a circuit block diagram of a sum-of-products calculation apparatus according to still another embodiment of the present disclosure.

### DESCRIPTION OF THE EMBODIMENTS

To make the content of the present disclosure more comprehensible, the following embodiments are used as examples for which the present disclosure may be implemented accordingly. In addition, wherever possible, elements/components/steps with the same reference numbers in the drawings and embodiments represent the same or similar components.

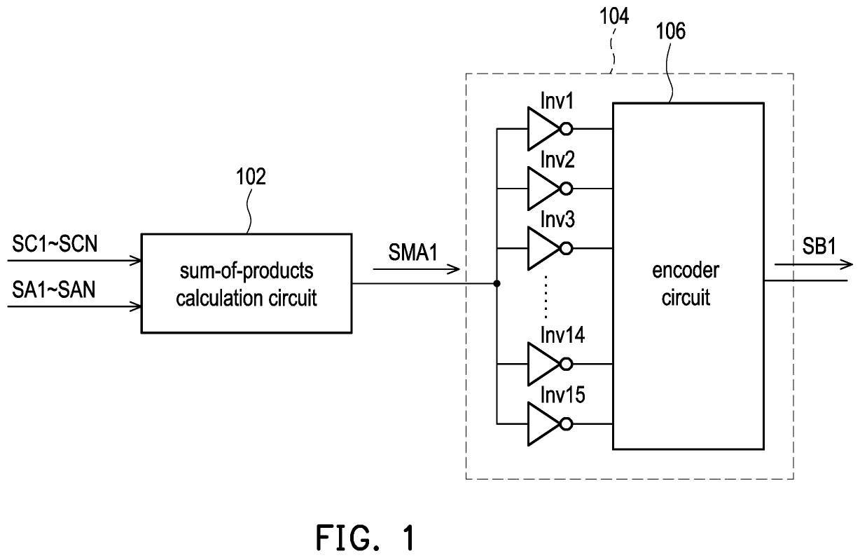

Please refer to FIG. 1 below. FIG. 1 is a circuit block diagram of a sum-of-products calculation apparatus according to an embodiment of the present disclosure. The sum-of-products calculation apparatus includes a sum-of-products calculation circuit 102 and an analog-digital conversion circuit 104, and the sum-of-products calculation circuit 102 is coupled to the analog-digital conversion circuit 104. The sum-of-products calculation circuit 102 performs a sum-of-products calculation on a plurality of weight signals SC1 to SCN and a plurality of analog input signals SA1 to SAN, where N is a positive integer, to output an analog sum-of-products signal SMA1. The analog-to-digital conversion circuit 104 converts the analog sum-of-products signal SMA1 into a digital signal SB1.

Furthermore, the analog-to-digital conversion circuit 104 may include a plurality of inverters InV1 to InV15 and an encoder circuit 106. The input terminal and output terminal of respective inverters InV1 to InV15 are respectively coupled to the sum-of-products calculation circuit 102 and the encoder circuit 106. The inverters InV1 to InV15 respectively have different threshold voltages, and they generate a corresponding bit signal in response to the analog sum-of-products signal SMA1. For example, in this embodiment, the inverter InV1 may be adapted to generate the lowest bit signal, and the inverter InV15 may be adapted to generate the highest bit signal. The bit signals generated by the inverters InV1 to InV15, for example, constitute a thermometer code (but the disclosure is not limited thereto) to represent the signal value of the analog sum-of-products signal SMA1.

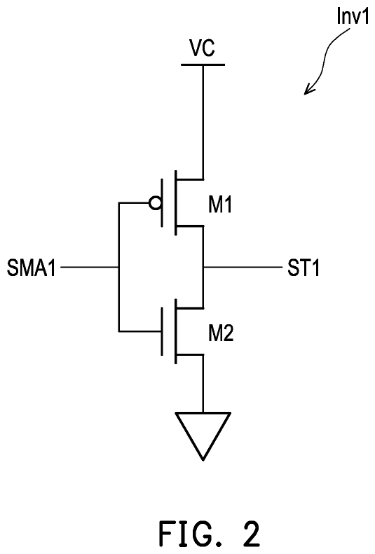

Furthermore, the respective inverters InV1 to InV15 may be implemented as shown in FIG. 2. In the embodiment of FIG. 2, the inverter InV1 is taken as an example, whereas the inverters InV2 to InV15 may be implemented in the same manner. In FIG. 2, the inverter InV1 may include a P-type transistor M1 and an N-type transistor M2. The P-type transistor M1 and the N-type transistor M2 are coupled between an operating voltage VC and a reference voltage. In this embodiment, the reference voltage is the ground voltage, but it is not limited thereto. The gates of the P-type transistor M1 and the N-type transistor M2 are coupled to the sum-of-products calculation circuit 102 to receive the analog sum-of-products signal SMA1. The common contact of the P-type transistor M1 and the N-type transistor M2 is coupled to the encoder circuit 106. The inverter InV1 generates a corresponding bit signal ST1 on the common contact of the P-type transistor M1 and the N-type transistor M2 in response to the analog sum-of-products signal SMA1. As mentioned above, the inverters InV1 to InV15 have different threshold voltages. In this embodiment, the threshold voltage of each of the inverters InV1 to InV15 is different in response to the channel width-to-length ratio of the P-type transistor M1 and the N-type transistor M2. In other words, the respective threshold voltages of the inverters InV1 to InV15 may be designed by adjusting the channel width-to-length ratio of the P-type transistor M1 and the N-type transistor M2. For example, the P-type transistor M1 of respective inverters InV1 to InV15 has the same channel width, and the N-type transistor M2 of each inverter has the same channel width. The threshold voltage of respective inverters InV1 to InV15 may be adjusted by making the P-type transistor M1 and the N-type transistor M2 of respective inverters InV1 to InV15 have different channel lengths.

In addition, the encoder circuit 106 encodes the bit signals generated by the inverters InV1 to InV15 to generate the digital signal SB1. For example, the encoder circuit 106 encodes the thermometer code formed by the bit signals generated by the inverters InV1 to InV15 into a binary signal (in this embodiment, it may be encoded as a 4-bit binary signal, but it is not limited thereto) to be output as the digital signal SB1. In some embodiments, the encoder circuit 106 may be implemented as, for example, a logic circuit, but it is not limited thereto. The encoder circuit 106 may also encode the bit signals generated by the inverters InV1 to InV15 into digital signals SB1 with reference to a lookup table (for example, a lookup table for converting the thermometer codes to the binary codes).

In this way, the inverters InV1 to InV15 and the encoder circuit 106 with different threshold voltages may quickly convert the analog sum-of-products signal SMA1 into a digital signal SB1 without the need to provide additional current or voltage, and so there is no static bias current but the transition current, and the transition time is extremely short. This provides the advantages of low power consumption and high conversion efficiency, sparing the users the disadvantages like poor working efficiency and high power consumption of a successive-approximation ADC. In addition, the circuit architectures of the inverters InV1 to InV15 and the encoder circuit 106 do not have the disadvantage of a large circuit area of the successive-approximation ADC. Therefore, the sum-of-products calculation apparatus may better meet the requirements of the analog-to-digital conversion circuit for the sum-of-products calculation apparatus.

It is worth noting that although the above embodiments illustrate the analog-to-digital conversion circuit 104 with 15 inverters InV1 to InV15, the number of inverters is not limited to the above embodiments. In other embodiments, the analog-to-digital conversion circuit 104 may include more or fewer inverters.

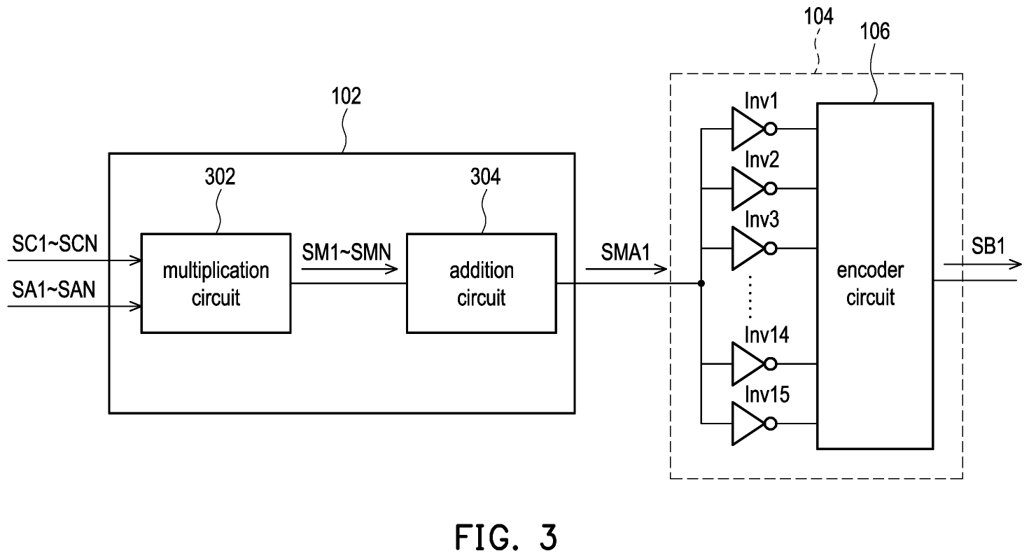

FIG. 3 is a circuit block diagram of a sum-of-products calculation apparatus according to another embodiment of the present disclosure. Furthermore, a sum-of-products calculation circuit 102 of the sum-of-products calculation apparatus may include a multiplication circuit 302 and an addition circuit 304, and the multiplication circuit 302 is coupled to the addition circuit 304. The multiplication circuit 302 receives a plurality of analog input signals SA1 to SAN and a plurality of weight signals SC1 to SCN, and performs a multiplication calculation on the weight signals SC1 to SCN and the analog input signals SA1 to SAN to generate a plurality of product signals SM1 to SMN. The addition circuit 304 adds the product signals SM1 to SMN together to generate an analog sum-of-products signal SMA1.

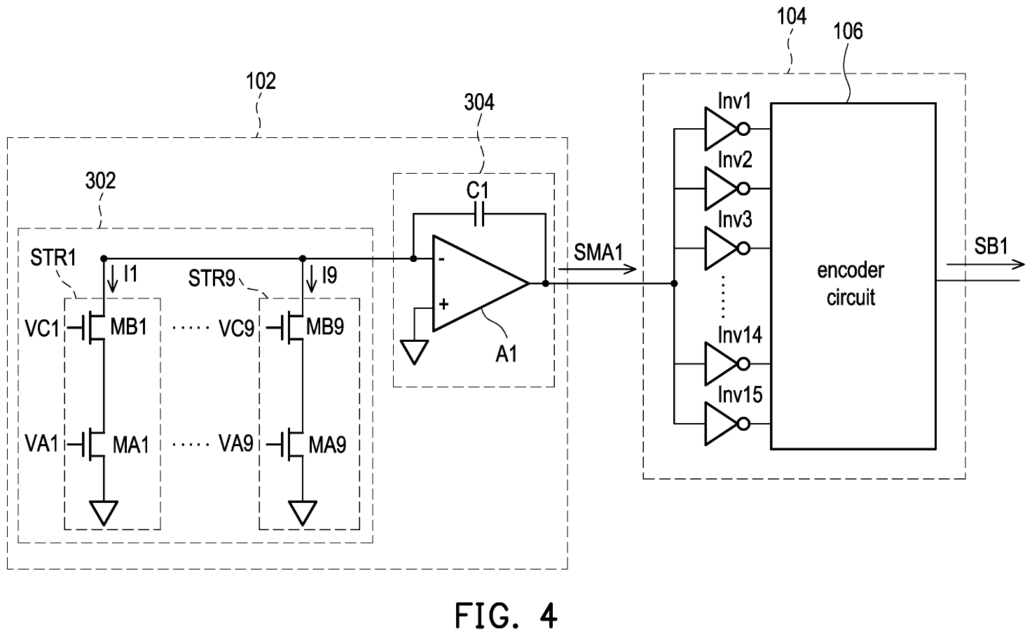

Specifically speaking, the multiplication circuit 302 and the addition circuit 304 may be implemented as shown in FIG. 4. The multiplication circuit 302 may include a plurality of transistor strings STR1 to STR9, and the addition circuit 304 may include a comparator A1 and a capacitor C1. The transistor strings STR1 to STR9 are coupled between the negative input terminal of the comparator A1 and the reference voltage (for example, the ground voltage, but the disclosure is not limited thereto). In addition, the positive input terminal of the comparator A1 is coupled to the transistor strings STR1 to STR9. The negative input terminal of the comparator A1 is coupled to the ground voltage. The output terminal of A1 is coupled to the input terminals of the inverters InV1 to InV15. The capacitor C1 is coupled between the positive input terminal and the output terminal of the comparator A1.

Furthermore, each transistor string may include two transistors connected in series. For example, the transistor string STR1 may include a transistor MA1 and a transistor MB1. The transistor MA1 is controlled by the corresponding analog input signal SA1 to change its conduction level, and is adapted to generate an input data current I1 at the corresponding transistor string. Furthermore, the transistor MB1 is controlled by the corresponding weight signal SC1 to change its conduction time to control the duration of providing the input data current I1. The signal value of the product signal SM1 provided by the transistor string STR1 reflects the current value and the duration of the input data current I1 provided by the transistor string STR1. Similarly, the signal values of the product signals SM2 to SM9 provided by the transistor strings STR2 to STR9 respectively reflect the current values and the duration of the input data currents I2 to I9 provided by them. Since its implementation is similar to the implementation of the transistor string STR1 providing the product signal SM1, the same description is not repeated here. After the input data currents I1 to I9 are integrated by the integrator formed by the comparator A1 and the capacitor C1, the voltage output by the comparator A1 represents the accumulated value of the products of the input data currents I1 to I9 and the weights (the conduction time of the transistors MB1 to MB9), and it also represents the sum (the analog sum-of-products signal SMA1) of the products of the analog input signals SA1 to SA9 and the weight signals SC1 to SC9.

It is worth noting that although this embodiment takes 9 transistor strings STR2 to STR9 as an example to exemplify the sum-of-products calculation circuit 102, the number of transistor strings is not limited to this embodiment. In other embodiments, the sum-of-products calculation circuit 102 may include more or fewer transistor strings.

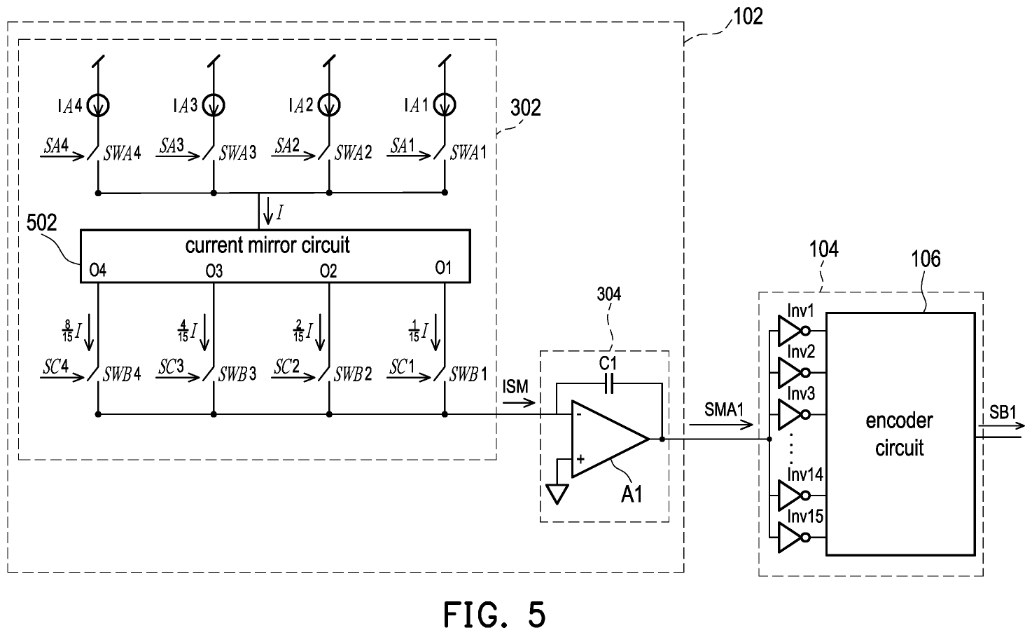

FIG. 5 is a circuit block diagram of a sum-of-products calculation apparatus according to still another embodiment of the present disclosure. In this embodiment, a multiplication circuit 302 includes a plurality of current sources IA1 to IA4, switches SWA1 to SWA4, a current mirror circuit 502, and switches SWB1 to SWB4. The switches SWA1 to SWA4 are coupled between the corresponding current sources IA1 to IA4 and the current mirror circuit 502. The current mirror circuit 502 has a plurality of output terminals O1 to O4. The switches SWB1 to SWB4 are coupled between the output terminals O1 to O4 of the corresponding current mirror circuit 502 and the negative input terminal of the comparator A1.

The current sources IA1 to IA4 respectively provide different currents. For example, the ratios between current values of the currents provided by the current sources IA1 to IA4 constitute a geometric sequence. For example, the current values of the current provided by the current sources IA1 to IA4 may be 0.1 uA, 0.2 uA, 0.4 uA, and 0.8 uA in order, but it is not limited thereto. The switches SWA1 to SWA4 may be controlled by the analog input signals SA1 to SA4 to change their conduction state, and the turned-on switches provide the current of its corresponding current sources to the current mirror circuit 502. For example, assuming that in this embodiment the switches SWA1 to SWA3 are turned on and the switch SWA4 is turned off, then the switches SWA1 to SWA3 provide current values of 0.1 uA, 0.2 uA, and 0.4 uA, respectively, which makes the current value of the current I received by the current mirror circuit 502 0.7 uA.

The current mirror circuit 502 outputs multiple currents from its output terminals O1 to O4 according to the currents provided by the turned-on switches SWA1 to SWA3. The ratios between the current values of these currents constitute a geometric sequence. For example, in this embodiment, the output terminals O1 to O4 respectively output current values of I/15, 2I/15, 4I/15, and 8I/15, but it is not limited thereto. The switches SWB1 to SWB4 may be controlled by the weight signals SC1 to SC4 to change their conduction state, and the turned-on switches provide the current of its corresponding output terminal to the negative input terminal of the comparator A1. For example, assuming that in this embodiment, the switches SWB1 and SWB3 are turned on and the switches SWB2 and SWB4 are turned off, the switches SWB1 and SWB3 provide currents of I/15 and 4I/15 respectively, which makes the current value of the current ISM received by the negative input terminal of the comparator A1 5I/15. After the current ISM is integrated by the integrator formed by the comparator A1 and the capacitor C1, the voltage output by the comparator A1 represents the sum (the analog sum-of-products signal SMA1) of the products of the analog input signals SA1 to SA4 and the weight signals SC1 to SC4. It is worth noting that although this embodiment takes 4 current sources IA1 to IA4, 4 switches SWA1 to SWA4, and 4 switches SWB1 to SWB4 as examples to exemplify the sum-of-products calculation circuit 102, the number of switches and current sources is not limited to this embodiment, and the relationship among the current values of the currents provided by the current sources IA1 to IA4 and the relationship among the current values of the currents provided by the output terminals O1 to O4 of the current mirror circuit 502 are not limited to this embodiment.

In summary, the sum-of-products calculation apparatus of the embodiments of the present disclosure includes an analog-to-digital conversion circuit having an encoder circuit and a plurality of inverters, the inverters have different threshold voltages and may generate a plurality of bit signals in response to an analog sum-of-products signal, and the encoder circuit may encode the bit signals to generate a digital signal. In this way, the analog-to-digital conversion circuit has the advantages of high conversion efficiency, low power consumption, and small circuit area, meeting the requirements of the analog-digital conversion circuit for the sum-of-products calculation apparatus, which expands the feasibility of the sum-of-products calculation apparatus in artificial intelligence technology.

Although the present disclosure has been disclosed in the above embodiments, they are not intended to limit the present disclosure. Anyone with ordinary knowledge in the technical field can make some changes and modifications without departing from the spirit and scope of the present disclosure. The scope of protection of the present disclosure shall be subject to those defined by the claims attached.

What is claimed is:

1. A sum-of-products calculation apparatus, comprising:
a sum-of-products calculation circuit, adapted to perform a sum-of-products calculation on a plurality of weight signals and a plurality of analog input signals to output an analog sum-of-products signal; and
an analog-digital conversion circuit, coupled to the sum-of-products calculation circuit, adapted to convert the analog sum-of-products signal into a digital signal, the analog-digital conversion circuit comprising:
a plurality of inverters, coupled to the sum-of-products calculation circuit, wherein the inverters respectively have different threshold voltages, and the inverters generate a plurality of bit signals in response to the analog sum-of-products signal; and
an encoder circuit, coupled to the inverters, adapted to encode the bit signals to generate the digital signal.

2. The sum-of-products calculation apparatus according to claim 1, wherein the encoder circuit encodes the bit signals into the digital signal with reference to a lookup table.

3. The sum-of-products calculation apparatus according to claim 1, wherein the bit signals constitute a thermometer code.

4. The sum-of-products calculation apparatus according to claim 3, wherein the digital signal is a binary signal.

5. The sum-of-products calculation apparatus according to claim 1, wherein the inverters respectively comprise:
a P-type transistor; and
an N-type transistor, connected in series with the P-type transistor between an operating voltage and a reference voltage, wherein gates of the P-type transistor and the N-type transistor are coupled to the sum-of-products calculation circuit, and the bit signals corresponding to the respective inverters are generated at a common contact of the P-type transistor and the N-type transistor.

6. The sum-of-products calculation apparatus according to claim 5, wherein a threshold voltage of the respective inverters is different in response to a channel width-to-length ratio of the P-type transistor and the N-type transistor.

7. The sum-of-products calculation apparatus according to claim 6, wherein the P-type transistor of the respective inverters has same channel width with each other, and the N-type transistor of the respective inverters has same channel width with each other.

8. The sum-of-products calculation apparatus according to claim 1, wherein the sum-of-products calculation circuit comprises:
a multiplication circuit, adapted to receive the analog input signals and the weight signals and perform a multiplication calculation on the weight signals and the analog input signals to generate a plurality of product signals; and
an addition circuit, coupled to the multiplication circuit, adapted to add the product signals together to generate the analog sum-of-products signal.

9. The sum-of-products calculation apparatus according to claim 8, wherein the addition circuit comprises:
a comparator, having a positive input terminal for receiving the product signals; a negative input terminal coupled to a reference voltage; and an output terminal coupled to input terminals of the inverters; and
a capacitor, coupled between the positive input terminal and the output terminal of the comparator, wherein the output terminal of the comparator outputs the analog sum-of-products signal.

10. The sum-of-products calculation apparatus according to claim 9, wherein the multiplication circuit comprises a plurality of transistor strings coupled between the negative input terminal of the comparator and the reference voltage, the transistor strings provide the product signals, and the transistor strings respectively comprise:
a first transistor, controlled by the corresponding analog input signals to change a conduction level, and adapted to generate an input data current at the corresponding transistor strings; and
a second transistor, controlled by the corresponding weight signals to change a conduction time to control a duration of providing the input data current, wherein a signal value of the respective product signals reflects a current value and a duration of the input data current provided by the corresponding transistor strings.

11. The sum-of-products calculation apparatus according to claim 9, wherein the multiplication circuit comprises:
a plurality of first current sources, adapted to provide a plurality of currents;
a plurality of first switches, coupled to the corresponding first current sources, wherein a conduction state of the first switches is controlled by the analog input signals;
a current mirror circuit, coupled to the first switches and comprising a plurality of output terminals, adapted to provide a plurality of currents from the output terminals according to the currents provided by the first switches that are turned on; and
a plurality of second switches, respectively coupled between the corresponding output terminals of the current mirror circuit and the negative input terminal of the comparator, wherein a conduction state of the second switches is controlled by the weight signals.

12. The sum-of-products calculation apparatus according to claim 11, wherein ratios between current values of the currents provided by the first current sources constitute a geometric sequence, and ratios between current values of the currents provided by the output terminals of the current mirror circuit constitute a geometric sequence.

13. The sum-of-products calculation apparatus according to claim 1, wherein the sum-of-products calculation apparatus is an artificial intelligence calculation apparatus or an edge calculation apparatus.
